(19) United States
(12) Patent Application Publication
(10) Pub. No.: US 2012/0286141 A1
(43) Pub. Date: Nov. 15, 2012

(54) PIXEL WITH REDUCED 1/F NOISE

(76) Inventor: Bart DIERICKX, Edegem (BE)

(21) Appl. No.: 13/549,775

(22) Filed: Jul. 16, 2012

Related U.S. Application Data
(62) Division of application No. 12/770,262, filed on Apr. 29, 2010.

(51) Int. Cl. H01L 31/113; H01L 27/146

(52) U.S. Cl. 250/208.1; 257/290; 257/E31.085

(57) ABSTRACT

A pixel is provided, comprising at least one transistor, the pixel being arranged for cycling the at least one transistor between two or more bias states, e.g. inversion and accumulation, during a readout phase. Due to the cycling between the at least two bias states, the correlation over time of the 1/f noise of the readout signals is broken, thus taking multiple samples and applying an operator onto the samples can reduce the effect of the 1/f noise to arbitrary low levels.

### CROSS-REFERENCE TO RELATED APPLICATION

This application is a divisional of U.S. patent application Ser. No. 12/770,262, filed on Apr. 29, 2010, which is incorporated by reference herein in its entirety.

### FIELD OF THE INVENTION

The present invention relates to general image sensing, especially to the field of low intensity sensing, such as astronomy and various fields of scientific imaging. However, also many other imaging domains may benefit from the present invention, including but not limited to medical imaging, automotive imaging, machine vision, night vision, digital photography and digital camcorder image sensors. The present invention relates to a pixel with reduced 1/f noise, an image sensor with a plurality such pixels, and a method to operate it.

### BACKGROUND OF THE INVENTION

Image noise is the random variation of brightness or color information in images produced by the sensor and circuitry of an image sensor, and is an undesirable by-product of image capture. Many image sensor technologies have been or are applied to low noise imaging. The following list is an example but is not intended, however, to be an exhaustive list.

Charge coupled devices (CCDs), are still today considered as state of the art in low light low noise imaging. Proof is that many if not all of the high performance astronomical, space and scientific imagers in the visible range are CCDs. Key to the lowest read noise operation is the Correlated Double Sampling (CDS) operation. Further, CCDs have and inherited low dark current that may even be improved by features as “inversion mode”. CCDs exhibit a high quantum efficiency (QE) typically above 50% that can even be pushed to nearly 100% by backside thinning and backside illumination.

A variation of CCD is a charge injection device, where a charge packet is moved below multiple electrodes and read repetitively in a non-destructive fashion using a floating gate readout so as to oversample and reduce the read noise.

Over time, CMOS image sensors have gradually taken over the fields where CCDs have been superior. As also CMOS can exploit CDS, CMOS sensors with noise performance rivaling that of CCDs have been reported, having noise equivalent charge (QN) as low as 1 to 2 electrons_{RMS}. Also CMOS can be combined with backside thinning and backside illumination, resulting in very high quantum efficiency (QE).

U.S. Pat. No. 7,432,968 discloses a CMOS image sensor including a plurality of pixels, each pixel including a plurality of transistors. The image sensor includes a controller for controlling operation of the plurality of pixels. The controller is configured to cause at least one of the transistors in each pixel circuit to be placed in an accumulation mode during an integration phase, and then switched from the accumulation mode to a strong inversion mode during a readout phase, thereby reducing 1/f noise of the pixels.

There is room for pixels and image sensors with still lower 1/f noise level.

### SUMMARY OF THE INVENTION

It is an object of embodiments of the present invention to provide a good method and device suitable for use in imaging at low irradiation, e.g. low light conditions such as for example at night vision, short shutter times.

The above objective is accomplished by a method and device according to embodiments of the present invention.

In a first aspect, the present invention provides a pixel comprising at least one transistor, the pixel being arranged for cycling the at least one transistor between two or more bias states during a readout phase.

The readout phase may be a readout phase for reading out a first signal level of the pixel, e.g. “reset level” or a readout phase for reading out a second signal level of the pixel, e.g. “actual signal level”. The pixel may be arranged for determining the first and/or second signal level by determining multiple readings of that signal level, in-between which a cycling between at least two bias states takes place, and applying an operator to the multiple readings, such as for example (but not limited thereto) averaging of the samples. Due to the cycling between the at least two bias states, the correlation over time of the 1/f noise of the signals read out is broken, thus taking multiple samples of a same signal level, e.g. reset level or actual signal level, and applying an operator onto the samples can reduce the effect of the 1/f noise to arbitrary low levels.

The pixel may be arranged for cycling the at least one transistor between two or more bias states during a readout phase at least once or twice, but clearly to have a large effect, the number of cycles back and forth should be sufficiently large. Some tens up to some hundred of cyclings between the at least two bias states are reasonable values.

It is an advantage of a pixel according to embodiments of the present invention that 1/f noise levels thereof are substantially reduced with respect to the noise levels of prior art pixels and methods for operating them.

In a pixel according to embodiments of the present invention, the at least one transistor arranged for being cycled between two or more bias states during a readout phase, may be a MOSFET being part of an amplifying or a buffering configuration.

A particular pixel according to embodiments of the present invention may be arranged for cycling the at least one transistor at least between inversion mode and accumulation mode.

A pixel according to embodiments of the present invention may be arranged for cycling the at least one transistor between two or more bias states by modulating a bulk potential of the at least one transistor. Alternatively, a pixel according to embodiments of the present invention may be arranged for cycling the at least one transistor between two or more bias states by modulating a gate potential of the at least one transistor. In yet alternative embodiments according to the present invention may be arranged for cycling the at least one transistor between two or more bias states by modulating a source and/or drain potential of the at least one transistor.

A pixel according to embodiments of the present invention may comprise a plurality of transistors, e.g. MOSFETs, wherein all transistors of the pixel are of a same type, for example n-type or p-type, e.g. nMOSFET or pMOSFET. Alternatively, a pixel according to embodiments of the present invention may comprise a plurality of transistors, e.g. MOSFETs, wherein the transistors of the pixel are of different types, for example the pixel may comprise mixed n-type and p-type transistors, e.g. mixed nMOSFET and pMOSFET.

A pixel according to embodiments of the present invention may comprise a plurality of transistors, wherein transistors of a same type are provided in a same substrate. Alternatively, transistors of a same type may be provided in separate substrates.

In a pixel according to embodiments of the present invention, transistors of a same type or transistors of different types may be provided in galvanically separated substrates. The substrates may be galvanically separated by any of a reverse biased junction, a dielectric layer e.g. in SOI, a physical separation, e.g. air or vacuum. The pixel may be implemented in a hybrid or semi hybrid setup.

A pixel according to embodiments of the present invention may comprise a photoreceptor, wherein the photoreceptor has a potential gradient towards a location arranged for collecting charges. In embodiments of the present invention, the potential gradient may be realized by a continuous or stepwise change in doping profile of the photoreceptor. In alternative embodiments, the potential gradient may be realized by a continuous or stepwise change in doping profile of a pinning layer pinning the photoreceptor. In yet alternative embodiments, the potential gradient may be realized by a continuous or stepwise change in doping level of the substrate in which the photoreceptor is located.

In a second aspect, the present invention provides an array of pixels comprising a plurality of pixels according to embodiments of the first aspect.

In a third aspect, the present invention provides an image sensor comprising at least one pixel as in embodiments of the first aspect of the present invention or an array of pixels as in embodiments of the second aspect of the present invention.

An image sensor according to embodiments of the present invention may furthermore comprise a controller arranged for cycling the at least one transistor between the two or more bias states.

An image sensor according to embodiments of the present invention may furthermore comprise circuitry arranged for performing an operator on pixel samplings after (each) cycling of the at least one transistor between two or more bias states. The operator may be a mathematical or electrical operator. The operator may for example be any of the following, the invention, however, not being limited thereto: averaging, weighted averaging, median filtering, low pass filtering, band pass filtering, Kalman filtering, differencing. The operator may be applied in the digital or in the analog domain.

In a fourth aspect, the present invention provides a method for operating a pixel comprising at least one transistor. The method comprises cycling the at least one transistor between two or more bias states during a readout phase. In particular embodiments, cycling the at least one transistor between two or more bias states may comprise cycling the at least one transistor at least between inversion and accumulation.

In embodiments according to the fourth aspect of the present invention, cycling the at least one transistor between two or more bias states may comprise modulating a bulk potential of the at least one transistor. In alternative embodiments, cycling the at least one transistor between two or more bias states may comprise modulating a gate potential of the at least one transistor. In yet alternative embodiments, cycling the at least one transistor between two or more bias states may comprise modulating a source and/or drain potential of the at least one transistor.

A method according to embodiments of the present invention may comprise collecting multiple pixel samplings during the readout phase, between cycling the at least one transistor between two or more bias states, and performing a further operator, e.g. averaging, low pass filtering, band pass filtering, medial filtering, Kalman filtering, etc. . . . on the multiple pixel samplings.

In a fifth aspect, the present invention provides a method for processing a signal from a pixel or an array of pixels for sensing electromagnetic or particle radiation, the method comprising reducing the effective read noise by replacing each signal value by a quantized signal value. By doing this, the signal of the pixel or array of pixels may have a read noise of substantially less than 1 electron_{RMS}. Replacing the signal by a quantized signal may be performed either on-chip or off-chip.

Particular and preferred aspects of the invention are set out in the accompanying independent and dependent claims. Features from the dependent claims may be combined with features of the independent claims and with features of other dependent claims as appropriate and not merely as explicitly set out in the claims.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

### BRIEF DESCRIPTION OF THE DRAWINGS

FIG. 1 illustrates a first example of a pixel capable of implementing the present invention, wherein the amplifying transistor is implemented as a source follower.

FIG. 2 illustrates a second example of a pixel capable of implementing the present invention, wherein the amplifying transistor is implemented as an inverting feedback amplifier.

FIG. 3 and FIG. 4 illustrate examples of pixels that can be driven according to embodiments of the present invention, wherein the MOSFET of the amplifier (which is a source follower in both cases illustrated, is pulsed from inversion to accumulation by capacitive coupling of the gate through a capacitor C_{C}.

FIG. 5, FIG. 6 and FIG. 7 illustrate possible cross-sections of a pixel as illustrated in FIG. 2.

FIG. 8 illustrates a pinned photodiode implemented in a 3T pixel as may be used in accordance with embodiments of the present invention.

FIG. 9 illustrates linear diffusion length versus diffusion time, for electrons in bulk Silicon, at 300K.

FIG. 10 illustrates a first embodiment of a pixel with a lateral potential gradient (or depletion voltage gradient) where the gradient is created by multiple p-implants of different concentration and/or depth.

FIG. 11 illustrates a possible layout top view of the pixel illustrated in FIG. 10, showing how different p implants can overlap.

FIG. 12 illustrates a second embodiment of a pixel with a lateral potential gradient (or depletion voltage gradient) where the gradient is created by multiple n-implants of different concentration and/or depth.

FIG. 13 illustrates a third embodiment of a pixel with a lateral potential gradient (or depletion voltage gradient) where the gradient is created by multiple concentration zones in the p-substrate.

FIG. 14 illustrates signal and noise time traces in a prior art driving of pixels, in the case illustrated the pixels illustrated in FIG. 2.

FIG. 15 illustrates signal and noise time traces in a driving of pixels in accordance with embodiments of the present invention, in the case illustrated driving of a pixel as illustrated in FIG. 2, by pulsing the well connection of the amplifying MOSFET.

FIG. 16, FIG. 17 and FIG. 18 show simulated traces of 50 consecutive “readings” taken from a pixel an accordance with a method according to an embodiment of the present invention, wherein the resulting readings are resampled, e.g. rounded to the nearest integer number of electrons. FIG. 16 illustrates a case with noise being 1 _{electrons}_{RMS}, FIG. 17 illustrates a case with noise being 0.25 electrons_{RMS}, and FIG. 18 illustrates a case with noise being 0.1 electrons_{RMS}.

FIG. 19 illustrates a probability distribution (normalized to 1 at maximum) for the reading of a fixed signal with a standard deviation sigma of 0.25 electrons_{RMS}, thus corresponding to FIG. 17.

FIG. 20 shows a graph with on the X-axis the noise of the reading of a pixel assuming that the read noise is a Gaussian distribution with a certain standard deviation expressed in electrons_{RMS}, and on the Y-axis the RMS or standard deviation of the resampled signal also expressed in electrons_{RMS}.

The drawings are only schematic and are non-limiting. In the drawings, the size of some of the elements may be exaggerated and not drawn on scale for illustrative purposes.

In the different drawings, the same reference signs refer to the same or analogous elements.

Any reference signs in the claims shall not be construed as limiting the scope.

### DETAILED DESCRIPTION OF ILLUSTRATIVE EMBODIMENTS

One type of image sensor is an active pixel sensor (APS). APS image sensors are typically fabricated using Metal Oxide Semiconductor (MOS) processing technology, in particular for example Complementary Metal Oxide Semiconductor (CMOS) processing technology, and are typically referred to as (C)MOS image sensors. CMOS image sensors sense light by converting incident radiation (photons) into electronic charge (electrons) via the photoelectric effect. CMOS image sensors typically include a photoreceptor (e.g. photodiode) and several CMOS transistors for each pixel.

Existing CMOS image sensors include, but are not limited to, three-transistor (3T) and four-transistor (4T) pixel implementations. Pixel implementations with more than four transistors have also been implemented. The pixel circuits in these image sensors typically include a source follower transistor that is used to buffer the photoreceptor voltage onto a column line. In CMOS image sensors with 4T pinned photodiode pixel implementations read noise is typically dominated by the 1/f noise of the source follower transistor. 1/f noise, which is also referred to as flicker noise, has a spectral density that is inversely proportional to the frequency f. The 1/f noise of the source follower transistor is also a factor present in 3T pixel implementations, although there the 1/f noise is not typically dominant. Rather, in 3T pixel implementations, the read noise is typically dominated by “kTC” noise, which is the noise associated with resetting the pixel to a reset level. Nonetheless, 1/f noise from the source follower transistor also provides a significant contribution to the overall noise in 3T pixel implementations.

The generally accepted physical explanation for 1/f noise in MOSFETs is the McWorther theory. McWorther explains the fluctuations in the MOSFET current as being induced by coulomb states (a coulomb state is nothing else than a positive or negative electric point charge) near the interface between a semiconductor material and an insulating layer, e.g. a SiO₂-Si interface, that can change state by trapping or de-trapping a charge carrier. The presence of the Coulomb state at the interface affects the inversion layer hence the amount of current flowing. The trapping and de-trapping modulates the MOSFET current over time.

As the time constants involved with this trapping/detrapping range from very long times (minutes, even hours) to very short times (less than nanoseconds), the spectrum of the resulting noise has typically a specific nature where the noise spectral density is proportional to 1/frequency^{α}, where a is typically close to 1, hence resulting in the name “1/f noise”.

When only one such interface state is active in the MOSFET at a certain operating point, one can actually observe the trapping/detrapping. The current exhibits two levels, from which the nickname “Random Telegraph Signal” (RTS) noise. The spectrum of RTS is not 1/f, but has the so-called “Lorenzian spectrum”. As the superposition of many RTSs is the same as 1/f noise, the superposition of a many Lorenzian spectra results in the expected 1/frequency^{a} spectrum. An elaborate theory and experimental review of RTS noise and 1/f noise in MOSFETs may be found in following article, incorporated herein by reference: M. J. Kirton and M. J. Uren, “Noise in solid-state microstructures: A new perspective in individual defects, interface states and low-frequency (1/f) noise”, Advances in Physics, 1989, Vol.39 No.4, p.367-468.

In accordance with embodiments of the present invention, pixels are generated in which the 1/f noise sources are reduced or cancelled. Such pixels comprise at least one transistor, for example a MOSFET, and a controller. In accordance with embodiments of the present invention, if the pixel comprises a plurality of transistors, the transistor, e.g. MOSFET, generating most 1/f noise is arranged for being cycled between two or more bias states during a readout phase.

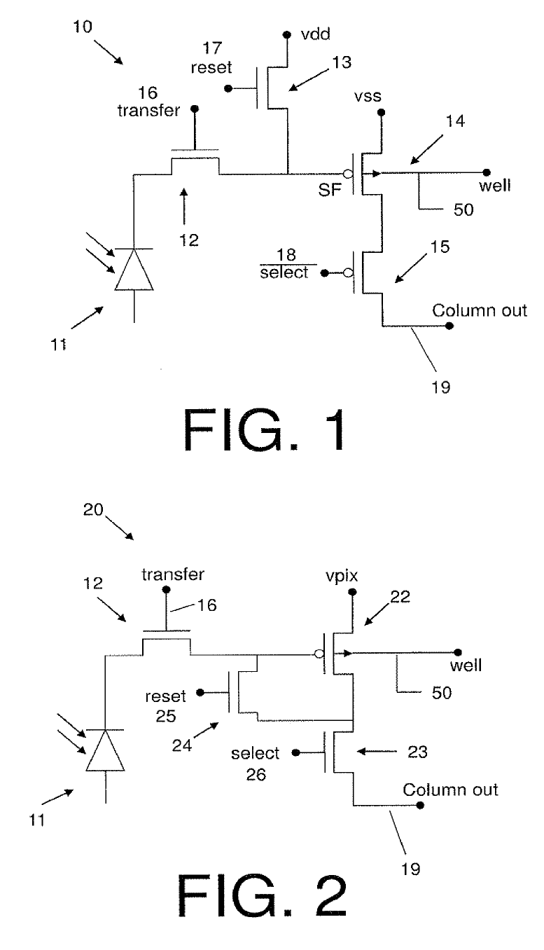

Examples of such pixels are illustrated in FIG. 1 and FIG. 2. Both figures illustrate 4T pixels, although the invention is not limited thereto and could as well be implemented in 3T pixels or other types of pixels comprising at least one transistor. In the pixels illustrated in FIG. 1 and FIG. 2, both transistors of a first type and transistors of a second type, e.g. nMOSFETs and pMOSFETs, respectively, are provided, which can be separately driven as illustrated below.

FIG. 1 is a schematic illustration of a four-transistor (4T) pixel 10 for a CMOS image sensor according to a first embodiment of the present invention. All transistors in the pixel are MOS transistors. The pixel 10 comprises a photoreceptor 11 for converting impinging radiation into electronic charge. The pixel 10 furthermore includes a sample and hold transistor 12, a reset transistor 13, a source follower transistor 14 and a column select transistor 15. Transistors 12 and 13 are illustrated as transistors of a first type, in the embodiment illustrated nMOS transistors, while transistors 14 and 15 are illustrated as transistors of a second type, in the embodiment illustrated pMOS transistors.

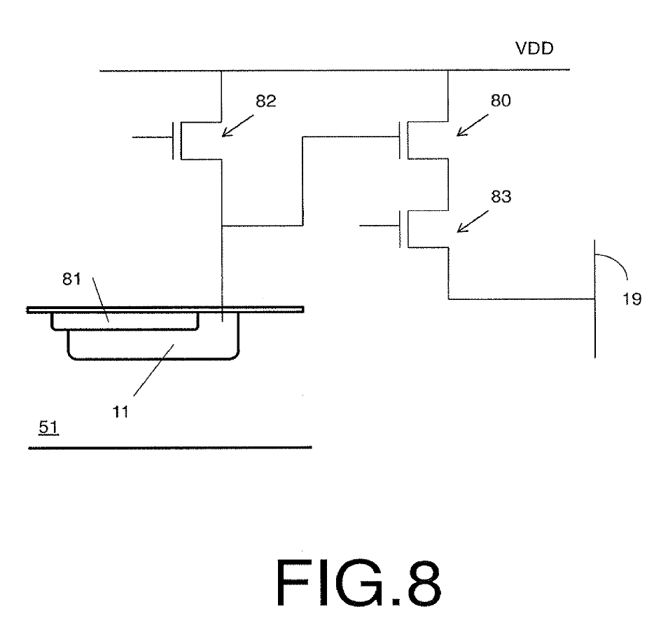

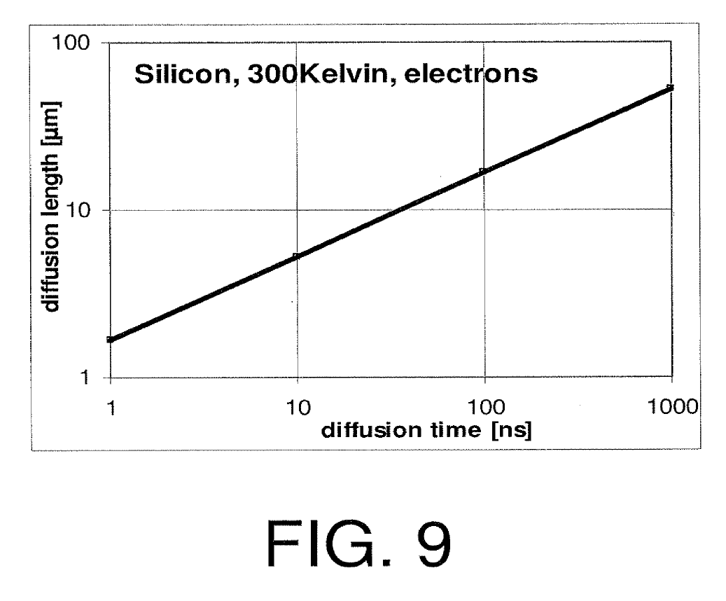

The photoreceptor 11 is connected between ground and the source of sample and hold transistor 12. The gate of the sample and hold transistor 12 is connected to a transfer line 16, and the drain of the sample and hold transistor 12 is connected to the source of the reset transistor 13 and to the gate of the source follower transistor 14. The drain of the reset transistor 13 is connected to voltage supply line vdd. The gate of the reset transistor 13 is connected to a reset line 17. The source of the source follower transistor 14 is connected to a voltage supply line vss. The drain of the source follower transistor 14 is connected to the source of the column select transistor 15. The gate of the column select transistor 15 is connected to a select line 18. The drain of the column select transistor 15 is connected to a column line 19. In the embodiment illustrated, the bodies of the transistors 12, 13 and 15 are connected to ground, while the body of transistor 14 is connected to a well potential. Hereto, the source follower transistor 14 is provided in a well, as illustrated in FIG. 7, FIG. 8 and FIG. 9 and discussed below. This way, the source follower transistor 14 can be driven separately from the other MOSFETs.

Reset transistor 13 is used to reset the voltage on the photoreceptor 11. Sample and hold transistor 12 is used for sensing and buffering the photoreceptor voltage. Source follower transistor 14 receives and amplifies the signal from the sample and hold transistor 12. Column select transistor 15 is used to select pixel 10 for readout.

Pixel information from a CMOS image sensor is typically sampled row per row. To select a row of pixels, the select line 18 is set high for the selected row of pixels 10. As, in the embodiment illustrated, the column select transistor 15 is a pMOS transistor, the inverse of the high signal on the select line triggers the transistor to switch on.

Pixel information for pixel 10 is typically generated and sampled in three phases; a pixel reset phase, an integration phase, and a readout phase.

During the reset phase, pixel 10 is reset by setting the reset line 17 and the transfer line 16 high (e.g. above vdd). Setting the reset line 17 high turns on reset transistor 13, and setting the transfer line 16 high turns on sample and hold transistor 12, and this sets the voltage across the photoreceptor 11 to a fixed starting value.

The reset line 17 and the transfer line 16 are then set to low (e.g. ground), thereby turning reset transistor 13 and sample and hold transistor 12 off and beginning the integration phase. While the reset line 17 and the transfer line 16 are low, pixel 10 integrates the amount of radiation focused onto photoreceptor 11, and photoreceptor 11 discharges from the reset level downward. At the end of the integration phase, the transfer line 16 is set to high to start the readout phase. Setting the transfer line 16 to high turns on sample and hold transistor 12, and causes the charge on the photoreceptor 11 to be transferred to the parasitic capacitance at the node connected to the gate of source follower transistor 13. The transfer line 16 is then set to low, thereby turning off sample and hold transistor 12.

For readout, the select line 18 is set to high, thus applying a low signal to the gate of the column select transistor 15. Setting the select line 18 to high, or thus applying a low signal to the gate of the column select transistor 15, switches on this latter transistor and transfers the integration voltage to the column out line 19, provided source follower transistor 14 is in conduction.

During the readout phase, the reset voltage and the integration voltage are typically both read subsequently from the column out line 19. The image signal generated by each pixel 10 is typically the difference between the read reset voltage and the voltage on the photoreceptor 11 after the integration period (i.e. the integration voltage).

In accordance with embodiments of the present invention, the effect of the 1/f noise is reduced by pulsing the MOSFET that is responsible for the 1/f noise, in the embodiment illustrated the source follower transistor 14, repetitively from a first state to a second state, e.g. from inversion to accumulation, and back, and oversampling it's signal, all during the same readout phase. The source follower transistor 14 may be placed in accumulation mode by providing voltages such that the gate voltage minus the bulk voltage is less than the threshold voltage for that transistor 14. The source follower transistor 14 may be placed in strong inversion mode by providing voltages such that the gate voltage minus the source voltage is larger than the threshold voltage for that transistor 14. This provision of voltages, in the embodiment illustrated in FIG. 1, may be obtained by repetitively pulsing the bulk voltage so that the above requirements for accumulation mode, resp. strong inversion mode are achieved.

FIG. 2 also illustrates a 4T pixel 20. Same elements as in FIG. 1 have a same reference number. Again all transistors in the pixel are MOS transistors. A difference with respect to FIG. 1 is that as amplifying transistor an inverting feedback amplifier 22 is provided. The inverting feedback amplifier 22, in the embodiment illustrated, is a pMOS transistor. The source of the inverting feedback amplifier 22 is connected to a power supply vpix. The drain of the inverting feedback amplifier 22 is connected to a drain of an nMOS column select amplifier 23. The gate of the inverting feedback amplifier 22 is connected to the drain of the sample and hold transistor 12. A reset transistor 24 is provided which is connected differently in the pixel 20: the reset transistor 24, in the embodiment illustrated, is an nMOS transistor, the source of which is electrically connected to the drain of the inverting feedback amplifier 22, while the drain of the reset transistor 21 is connected to the gate of the inverting feedback amplifier 22. The gate of the reset transistor 21 is connected to a reset line 25. In this embodiment, as indicated above, the column select transistor 23 also is an nMOS transistor. The gate of the column select transistor is connected to a select line 26. The source of the column select transistor 23 is connected to a column line 19 and the drain of the column select transistor 23 is connected to the drain of the inverting feedback amplifier 22.

The configuration illustrated in FIG. 2 is a kind of capacitive feedback charge amplifier or charge transimpedance amplifier (CTIA), for which the charge to voltage conversion ratio is dictated by a feedback capacitance, which in the case illustrated is the gate-drain capacitance of inverting feedback amplifier 22. For a person skilled in the art, it is clear that such pixel can be operated with higher charge to voltage conversion that the circuit in FIG. 1.

Also in this embodiment, the inverting feedback amplifier MOSFET 22 can be driven separately from the other MOSFETs in the pixel circuit. The inverting feedback amplifier 22 can be switched repetitively from a first state to a second state, e.g. from inversion to accumulation, and back, and it's signal can be oversampled. The inverting feedback amplifier 22 may be placed in accumulation mode by providing voltages such that the gate voltage minus the bulk voltage is less than the threshold voltage for that transistor 22. The inverting feedback amplifier 22 may be placed in strong inversion mode by providing voltages such that the gate voltage minus the source voltage is larger than the threshold voltage for that transistor 22. This provision of voltages, in the embodiment illustrated in FIG. 2, may be obtained by repetitively pulsing the bulk voltage so that the above requirements for accumulation mode, resp. strong inversion mode are achieved.

The interface states in MOSFETS, when cycled between different bias states (such as for example between accumulation mode and inversion mode), are forced to fill or empty their states much faster than when left to normal operation with little change in bias conditions. It has been found by the present inventor that, by doing so, long time correlation of the charge state is broken. By removing the long time correlation, the noise spectrum loses its predominant low frequency components and becomes “white noise”. It is well known to specialists in the field that a white noise spectrum and absence of correlation go hand in hand. Consecutive samples taken from a signal containing white noise are uncorrelated; hence, taking multiple samples and averaging them will reduce the noise as compared to the signal. The noise reduction is approximately proportional to the square root of the number of samples taken to calculate the average. As there is no real upper limit to the number of samples taken, apart from the time allowed by the application, one can thus reduce the effect of the noise to an arbitrarily low level.

For normal MOSFETs, the “useful” bias state is called “inversion” (where one makes the distinction weak and strong inversion). When an nMOSFET is biased “on”, the positive gate voltage will attract electrons towards the SiO2-Si interface, thereby “inverting” the p-type substrate material to an electron-rich “n”-layer. Accumulation is a state where the MOSFET is strongly turned off. Yet it is to be noted that in some types of MOSFETs, such as a buried channel MOSFET, accumulation is the on state, and inversion is the off state. One can consider many state of bias, such as various degrees of weak and strong accumulations or inversion. The state between accumulation and inversion is called “flat band”.

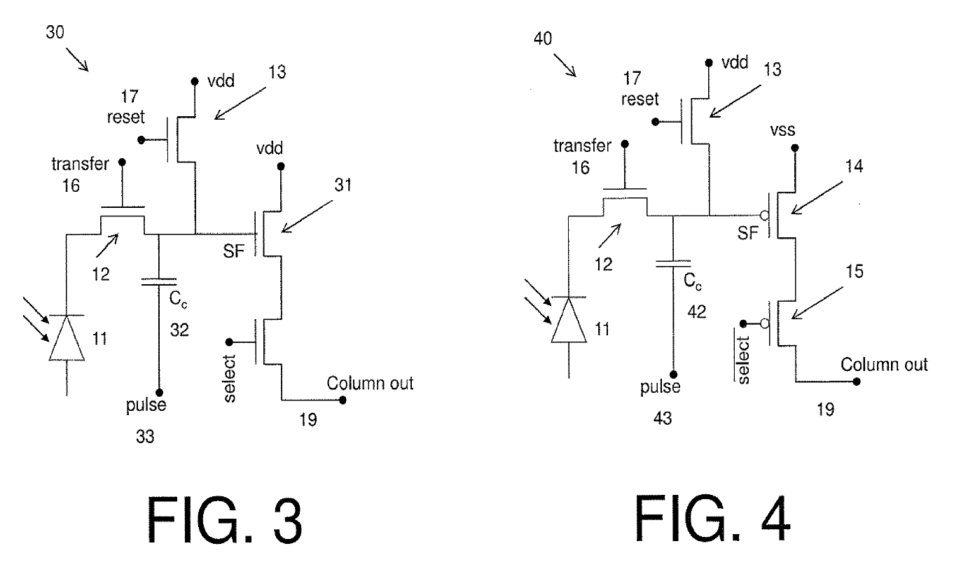

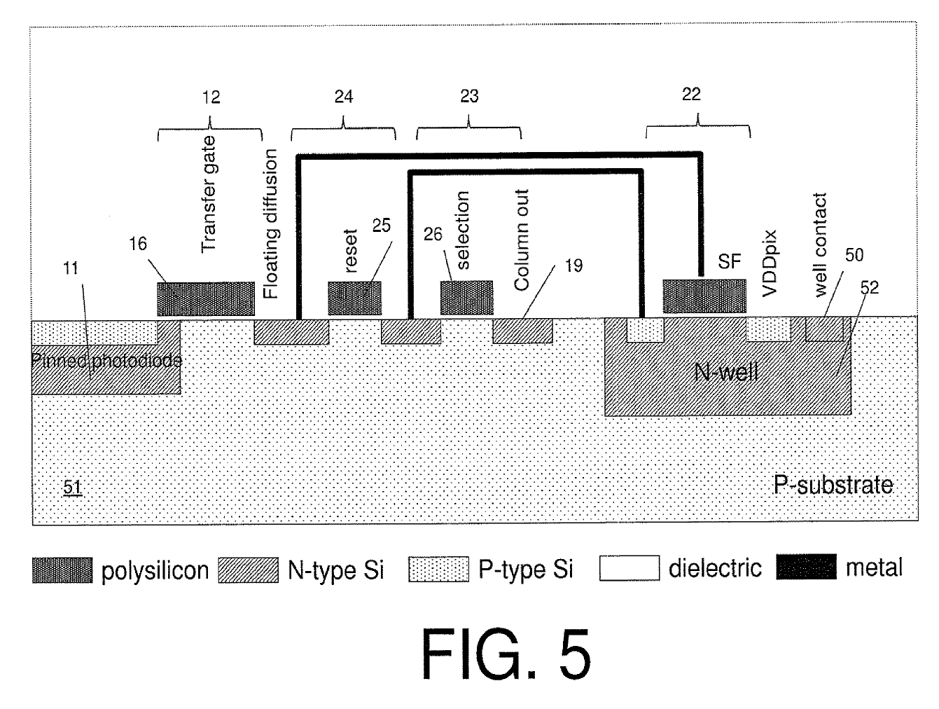

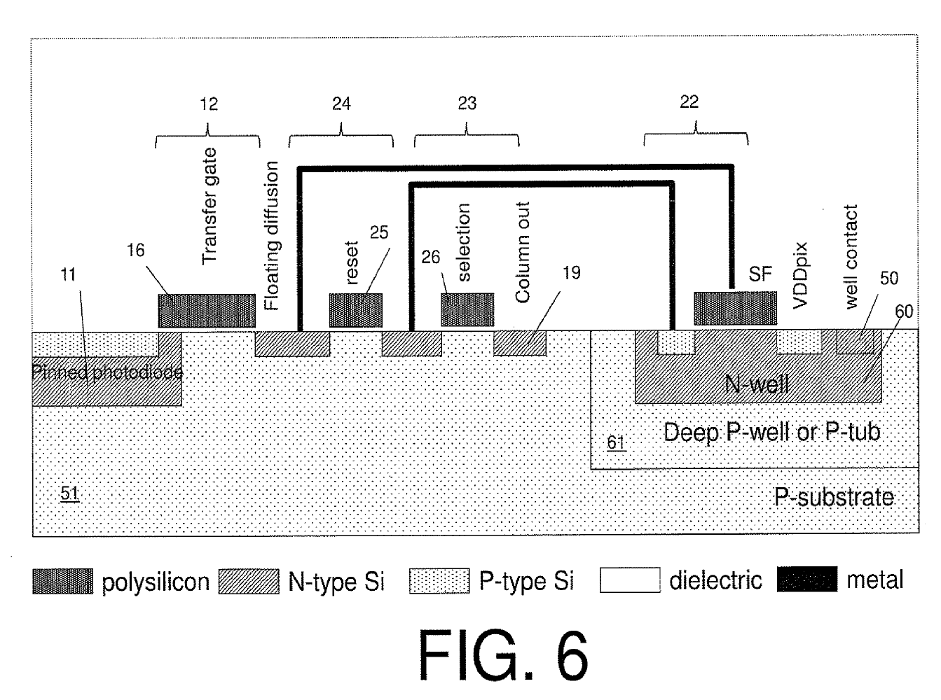

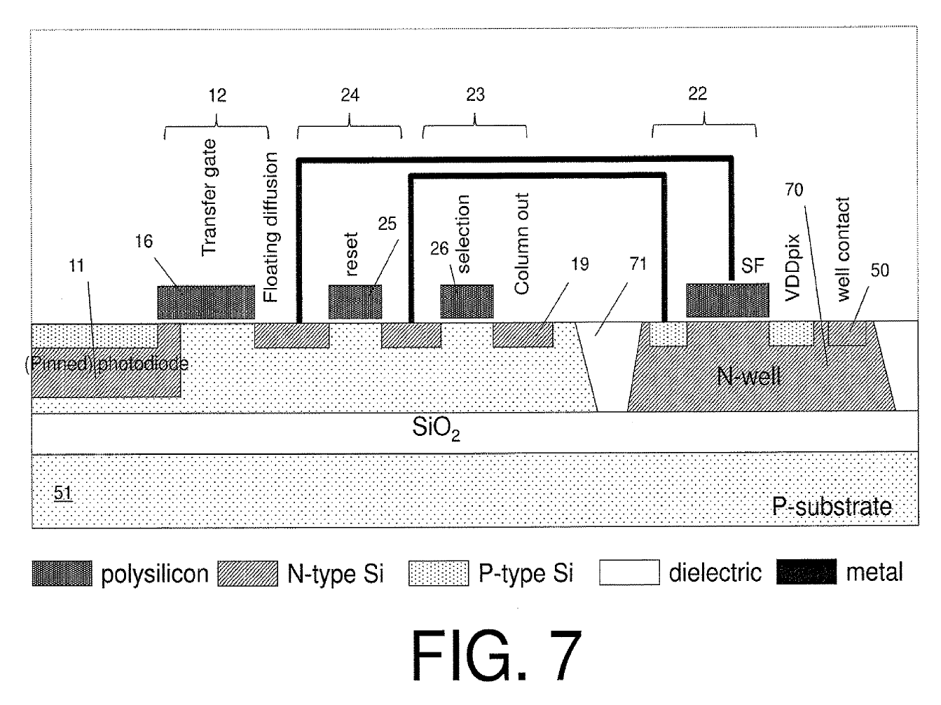

Pixels in accordance with embodiments of the present invention are designed with the capability in mind to cycle certain MOSFETs, in particular for example amplifying MOSFETs, between at least a first and a second mode, e.g. between inversion and accumulation, corresponding to on and off states of the MOSFETs. Such can be realized in many ways, of which a few are illustrated in FIG. 1 and FIG. 2, FIG. 3 and FIG. 4, FIG. 5 to FIG. 7.

Different techniques may be applied for switching the amplifying transistor, such as e.g. a source follower transistor or an inverting feedback amplifier, between an accumulation mode and a strong inversion mode in pixels of a CMOS image sensor according to embodiments of the present invention. Such techniques include pulsing of the substrate, or pulsing of the signal applied to the gate, and are described in further detail below.

Many classic pixels contain exclusively one type of MOSFET, typically nMOSFETs. In such pixels it is difficult to modulate one MOSFET's substrate as described with respect to the embodiments illustrated in FIG. 1 and FIG. 2, as this substrate is common for all, and often also is the substrate connection of the photoreceptor. In the embodiments illustrated in FIG. 1 and FIG. 2, modulating the MOSFETs' substrate so as to cycle the MOSFET between inversion and accumulation is made possible by providing different types of MOSFETs.

In accordance with the embodiments illustrated in FIG. 1 and FIG. 2, the cycling between the at least two states may be performed by cycling a well into which the amplifying MOSFET 14, 22 is provided. Therefore, a well contact 50 may be provided which may be suitably actuated.

When the substrate of the said amplifying MOSFETs must be isolated from the others, this can be done in various ways, such as for example, but not limited thereto:

By a junction, as in FIG. 5 and FIG. 6;
By a dielectric such as in FIG. 7, where this is based on a SOI process.
By other means know to persons skilled in the art to electrically isolate electrical nodes from each other.

FIG. 5 illustrates a possible cross-section of the pixel of FIG. 2. The photoreceptor 11 illustrated is a pinned photodiode. In the embodiment illustrated, the pinned photodiode is in the same substrate 51 as the MOSFET circuitry. As can be seen in the embodiment illustrated, the pMOSFET 22, which is the amplifying MOSFET 22, is provided in an nWELL 52 isolated from the other circuitry by a reverse biased junction.

FIG. 6 illustrates another possible cross-section of the pixel of FIG. 2. The photoreceptor 11 illustrated is a pinned photodiode. In the embodiment illustrated, the pinned photodiode is in the same substrate 51 as the MOSFET circuitry. As can be seen in the embodiment illustrated, the pMOSFET 22, which is the amplifying MOSFET 22, is provided in an nWELL 60 thus providing isolation by a reverse biased junction. Additionally, the pMOSFET's nWELL 60 is surrounded by a deep P-well or P-tub 61 which creates a potential gradient between the p-tub 61 and the p-substrate 51 that pushes away charge carriers, e.g. electrons, so that the nWELL 60 is not or less in competition with the real photodiode 11 for capturing photo-electrons.

FIG. 7 illustrates yet another possible cross-section of the pixel of FIG. 2. The photoreceptor 11 illustrated is a pinned photodiode. In the embodiment illustrated, the pinned photodiode 11 is in the same substrate 51 as the MOSFET circuitry. The pMOSFET 22, which is the amplifying MOSFET 22, is provided in an nWELL 70 which is isolated from the nMOSFET circuitry by means of a dielectric 71 as may be used in a SOI process.

In the above embodiments the amplifying MOSFET 22 is cycled between accumulation and inversion modes by cycling the substrate 51. In alternative embodiments one can cycle the amplifying MOSFET 22 between inversion and accumulation not by affecting the substrate 51, but by modulating its gate voltage sufficiently above and below the threshold voltage. Such can be done by proper circuit technique, e.g. by a capacitance coupling to the gate voltage, as shown in FIG. 3 and FIG. 4, where FIG. 3 contains only nMOSFETs, and FIG. 4 contains both nMOSFETs and pMOSFETs.

In accordance with the embodiments illustrated in FIG. 3 and FIG. 4, which illustrate pixels 30, 40 with a 4T layout as the pixels illustrated in FIG. 1, the cycling between the at least two states may be performed by cycling the gate of the amplifying MOSFET 31, 14. Hereto, a capacitive coupling 32, 42 to these gates may be provided. The capacitive coupling 32, 42, provides a means to capacitively influence the gate voltage of the MOSFET 31, 14 so that the MOSFET 31, 14 may be pulsed from inversion to accumulation and back. This capacitive coupling comprises a capacitor 32, 42 of which a first capacitor plate is electrically connected to the gate of the amplifying MOSFET 31, 14, and a second capacitor plate is electrically connected to an electrode onto which a PULSE signal 33, 43 may be applied.

At the end of the integration phase, charges collected on the photoreceptor 11 are transferred to the capacitor 32, 42. During the readout phase, i.e. after the collected charges have been transferred to the capacitor 32, 42, a pulse signal 33, 43 repetitively switching between a high and a low voltage value is applied to the second capacitor plate of the capacitor 32, 42. By doing this, the amplifying transistor 31, 14 repetitively gets into an accumulation mode and an inversion mode. When manufacturing pixels, for example 4T pixels or 3T pixels or pixels with any other suitable number of transistors, the photoreceptor 11 is often a buried or pinned photodiode. It is to be noted that also 3T pixels may make use of a pinned photodiode 11, as illustrated in FIG. 8. In such case, no transfer gate is provided, but a direct connection is made from the gate of the amplifying transistor 80 to the deep implant of the pinned diode 11. The photoreceptor diode 11 is pinned by a pinning layer 81 for forcing the charge collected by the photoreceptor diode towards the direct connection—see FIG. 8.

For large pixels, the time needed to transfer the charge, or to collect the charge becomes critically dependent on lateral diffusion of the photo carriers in the pinned diode 11. The time it takes for a free carrier to diffuse in the absence of an electrical field in linear direction grows as the square of the distance. This relation obeys

$${l}_{D} = \sqrt{{t}_{D} \cdot {μ}_{e} \cdot \frac{k T}{q}} ,$$

where I_{D} is the diffusion length or diffusion distance, t_{D} the diffusion time, μₑ the free carrier mobility, k the Boltzmann constant, T the absolute temperature in degrees Kelvin and q is the charge of a free carrier.

Table I shows an estimate of the diffusion time versus the diffusion distance, for linear diffusion in Silicon, assuming electrons with a bulk mobility of 1100 cm²/V.s at room temperature (300 K):

TABLE I

| Diffusion time | Diffusion distance |
|---|---|
| 1 ns | 1.7 μm |
| 10 ns | 5.2 μm |
| 100 ns | 17 μm |
| 1 μs | 52 μm |

This relationship is also represented in FIG. 9. It can be seen that the diffusion time becomes important compared to pixels' readout time (where a typical readout time for a row of pixels is in the order of 1 to 10 μs), for large pixels as those which may be used in accordance with embodiments of the present invention.

In order to speed up the time to collect the charges, one can create an internal electric field in the photo diode by various means. Such methods have for example been proposed in the past (such as for example in U.S. Pat. No. 6,683,360 “Multiple or graded epitaxial wafers for particle or radiation detection”, incorporated herein by reference in its entirety). Other suitable methods which may be used in combination with embodiments of the present invention may be based on creating an electric field by having a lateral impurity doping gradient in the photoreceptor.

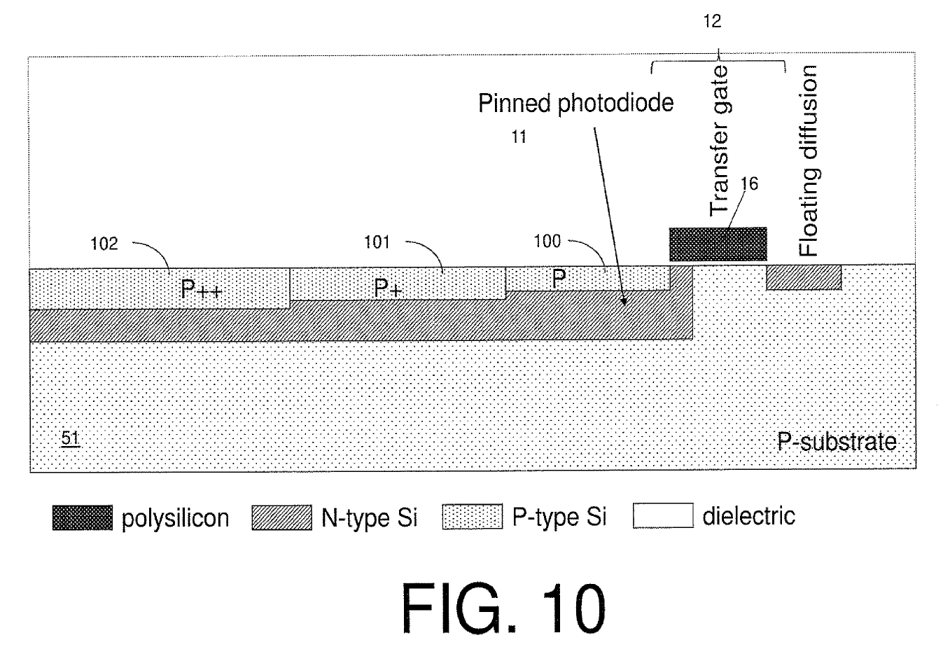

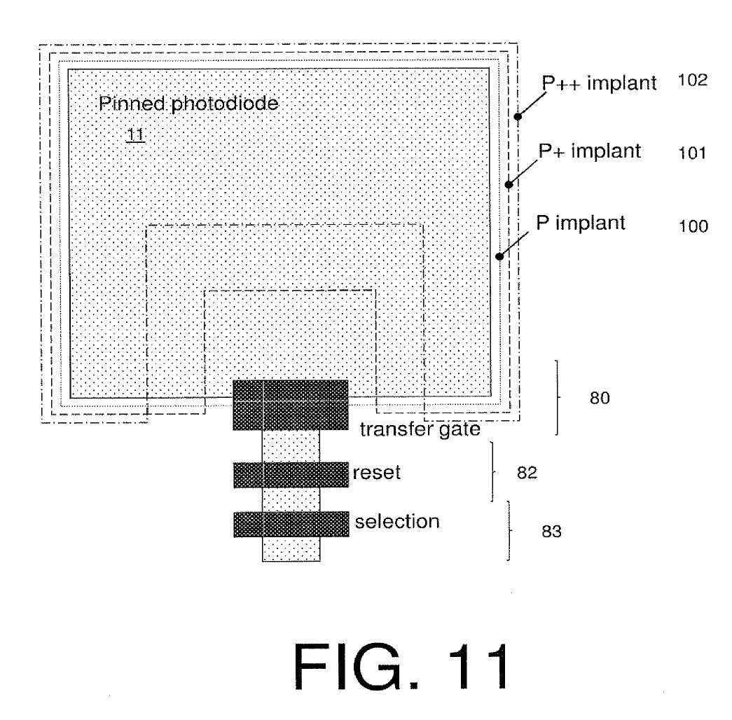

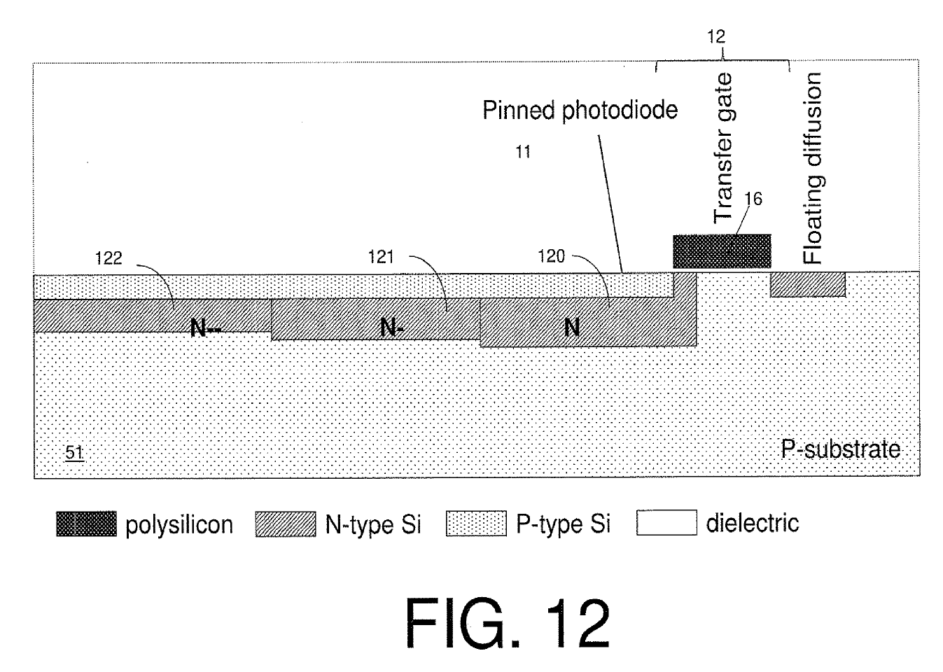

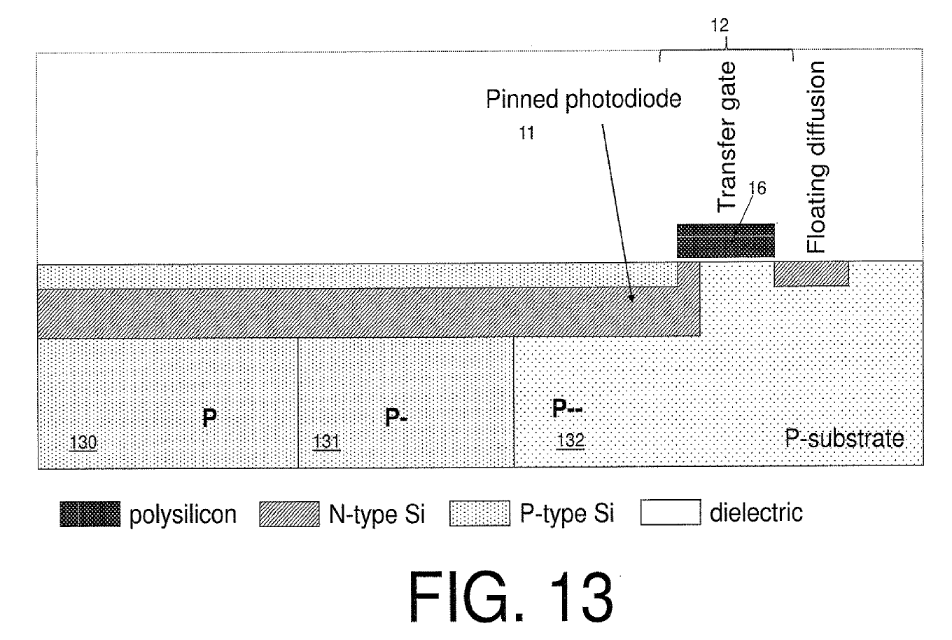

FIG. 10 and FIG. 11 show how such impurity or doping gradient may be realized by using multiple shallow implants of a pinning layer for pinning the photoreceptor 11, e.g. by multiple shallow p-type implants 100, 101, 102. There might be two or more implants adjacent one another, with increasing doping levels, as illustrated in side view in FIG. 10 or in top view in FIG. 11, or even a gradually increasing doping implant (not illustrated). Alternatively, the two or more implants may have different depths. In the embodiment illustrated in FIG. 12 the impurity or doping gradient is realized by multiple deep implants of the photoreceptor layer, e.g. multiple deep n-type implants 120, 121, 122. Also here there might be two or more implants with decreasing dopant level adjacent one another, as illustrated in FIG. 12, or alternatively a gradual doping profile (not illustrated). Alternatively, the two or more implants may have different depths. In the embodiment illustrated in FIG. 13 it is realized with a multiple or graded doping concentration 130, 131, 132 in the substrate or epitaxial layer under the pinned photodiode 11.

Methods for realizing such impurity or doping gradients are known to persons skilled in the art.

As illustrated above, lateral concentration gradient can apply to the shallow implant (FIG. 10 and FIG. 11), the deep implants (FIG. 12) and even the substrate (FIG. 13) of the pinned photodiode.

A pixel according to embodiments of the present invention, as illustrated above, may be used in a method according to embodiments of the present invention. In one embodiment, a method according to the present invention comprises operating the pixel as usual, by reading it out. The readout of the pixel may e.g. in raw mode, just reading the signal level after photocharge integration, or in double sampling (DS) where a readout of the signal level is followed by a readout of the reset level; or in correlated double sampling (CDS), where a readout of the reset level is followed by a readout of the signal level. The above list of readout methods for a pixel is not exhaustive, other methods to read a pixels may apply also.

Classically the levels read for the said reset and signal levels are usually single voltage levels (“samples”) that are then amplified, differenced or buffered toward the global output of the image sensor or towards an ADC.

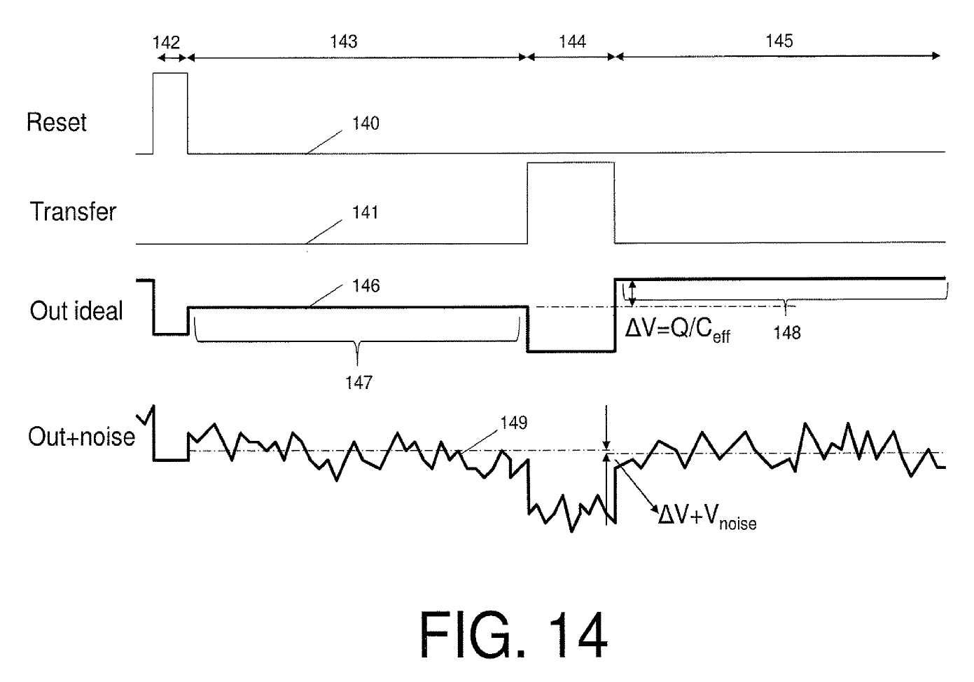

In accordance with embodiments of the present invention, multiple samples are taken for the reset and/or signal levels. Taking multiple samples for the same signal is often called “oversampling”, which is classically know as a technique for reducing noise, being understood that the multiple samples are then averaged. Such classical oversampling technique is presented in FIG. 14. FIG. 14 illustrates in a first graph 140 the reset signal applied, for example at a reset transistor in a 4T pixel. A second graph 141 illustrates the transfer signal, for example applied to a sample and hold transistor in a 4T pixel. The peaks in the graph 140 of the reset signal and in the graph 141 illustrating the transfer signal applied to a sample and hold transistor, define a reset phase 142, during which a photoreceptor 11 is reset to a starting voltage, a first readout phase 143, during which the reset voltage of the photoreceptor 11 is read out, a transfer phase 144, during which charges collected by the photoreceptor 11 are transferred to a memory element, such as a capacitor or a parasitic capacitor of an amplifying transistor 14, 22, and a second readout phase 145, during which the voltage level of the charges collected by the photoreceptor 11 is read out. Graph 146 in FIG. 14 illustrates an idealized readout signal, i.e. the signal as would be read out on the column line if no noise would be present. It can be seen from graph 146 that it comprises a first level 147 representing the reset voltage and a second level 148 representing the signal voltage. Graph 149 illustrates an example of a corresponding non-ideal signal, in which noise is present, with predominantly low frequency (1/f) noise. It can be seen that the averaged voltage level of the reset signal and the averaged voltage level of the signal voltage are not so much different. The signal after CDS, ΔV, suffers from a large component of the low frequency noise.

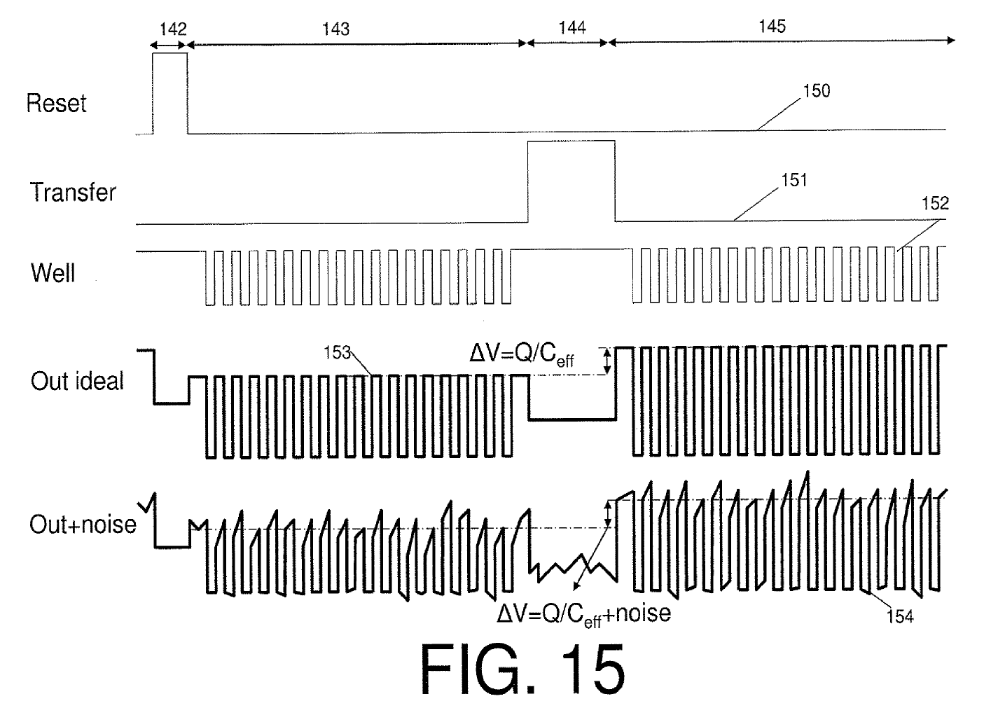

Inventive in the method according to embodiments of the present invention is that the MOS interface of (one or more) of the pixel's MOSFETs is cycled, during a readout phase 143, 145, between at least a first and a second state, e.g. between inversion and accumulation, between each or groups of the said multiple samples. This way, the signal is repeatedly sampled and averaged (or an operator equivalent to averaging is applied). This is also called oversampling. By doing so, as found in accordance with the present invention, the multiple samples lose the time correlation that is due to the 1/f or RTS noise. When the oversampling is followed by averaging, this will then result in a substantial reduction in noise. This is illustrated in FIG. 15, for a pixel as in FIG. 2 in which the amplifying transistor 22 is cycled between accumulation and inversion by pulsing the well connection 50. The reset phase 142, first readout phase 143, transfer phase 144 and second readout phase 145 are as in FIG. 14. Graph 150 in FIG. 15 illustrates the level of the reset signal and the timing of its pulses. Graph 151 illustrates the transfer signal applied to a sample and hold transistor. In the embodiment illustrated, the pixel is cycled between a first and a second state, e.g. between accumulation and inversion, during readout by applying a suitable voltage to the bulk of the amplifying transistor. This is illustrated in graph 152 of FIG. 15. It can be seen that, by doing so, the idealized output signal 153 of the pixel, i.e. the signal with no noise being present, jumps between two values, both during the first readout phase 143 and during the second readout phase 145. One of the extreme values of the readout signal during the first readout phase 143, e.g. the maximum value, corresponds to the reset level of the photoreceptor 11. One of the extreme values of the readout signal during the second readout phase 145, e.g. the maximum value, corresponds to the signal voltage of the photoreceptor 11. Graph 154 of FIG. 15 illustrates an example of a corresponding non-ideal signal, in which noise is present. It can be seen that the averaged extreme value corresponding to the readout signal during the first readout phase 143 and the averaged extreme value corresponding to the readout signal during the second readout phase 145 differ sufficiently to be distinguishable. The signal at the column out line includes the low frequency (1/f) noise. It can be seen that, although the noise is of the same magnitude as in FIG. 14, the noise is uncorrelated in time so that the average of the oversampled signal, after CDS, has a reduced noise content, so that ΔV is smaller.

The multiple samples during one readout phase may be combined in one “reading” in any suitable way, e.g. by averaging, by integration or by any other suitable operator, such as for example but not limited thereto, low pass or band pass filtering, using finite or infinite response filters, weighted averaging, linear or non-linear filtering, median filtering, Kalman filtering. It can happen in analog or digital domain. This operation can also be called ‘oversampling’.

Such reading may also include the effect of the DS or CDS, by making the difference between the reading of the reset level and the reading of the signal level. This combinations can happen in various ways in analog domain or in digital domain on-chip or off chip, as is known to persons skilled in the art.

The “readings” obtained as such are themselves considered as pixel signal values.

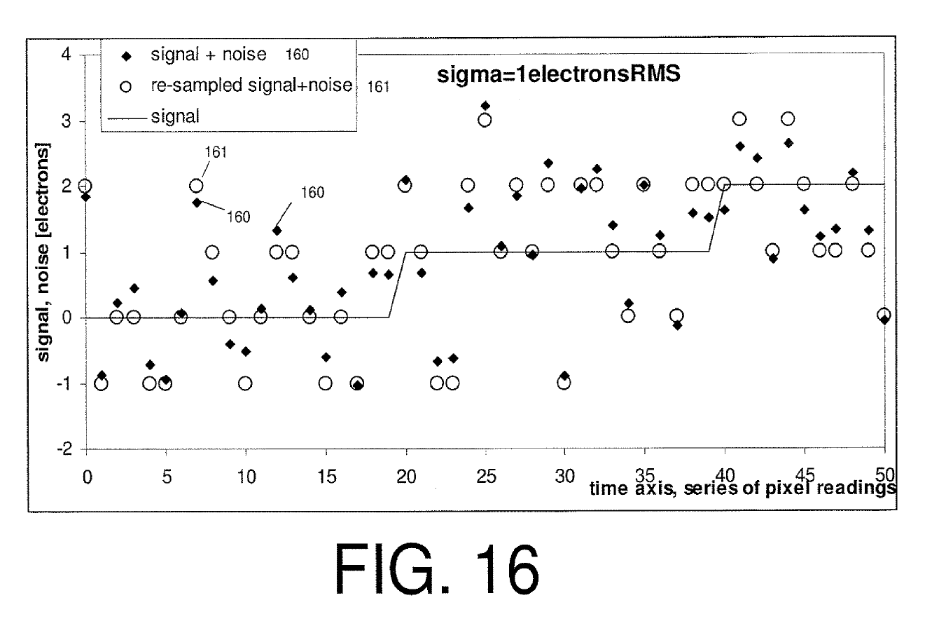

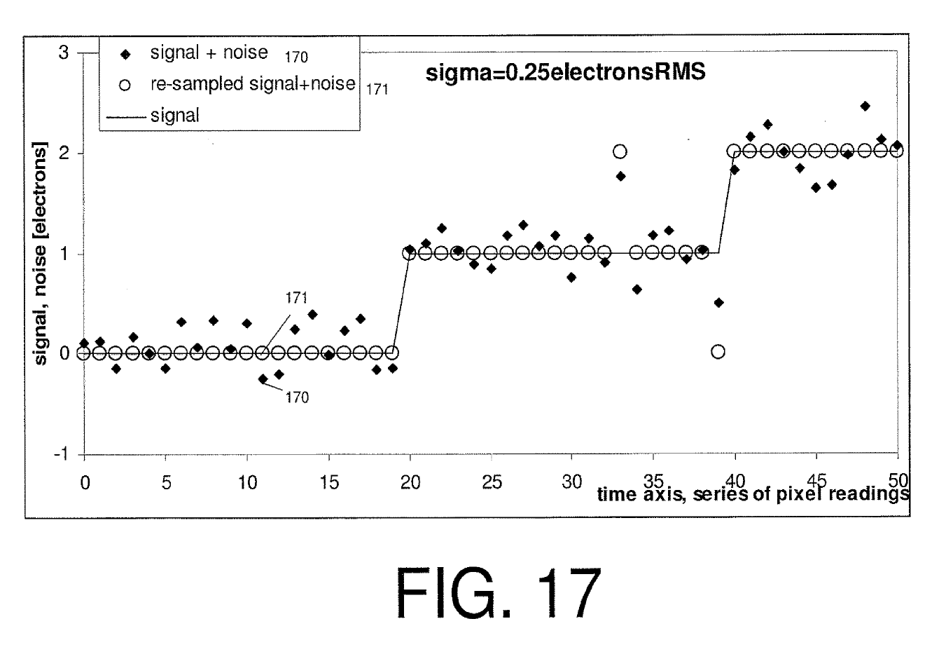

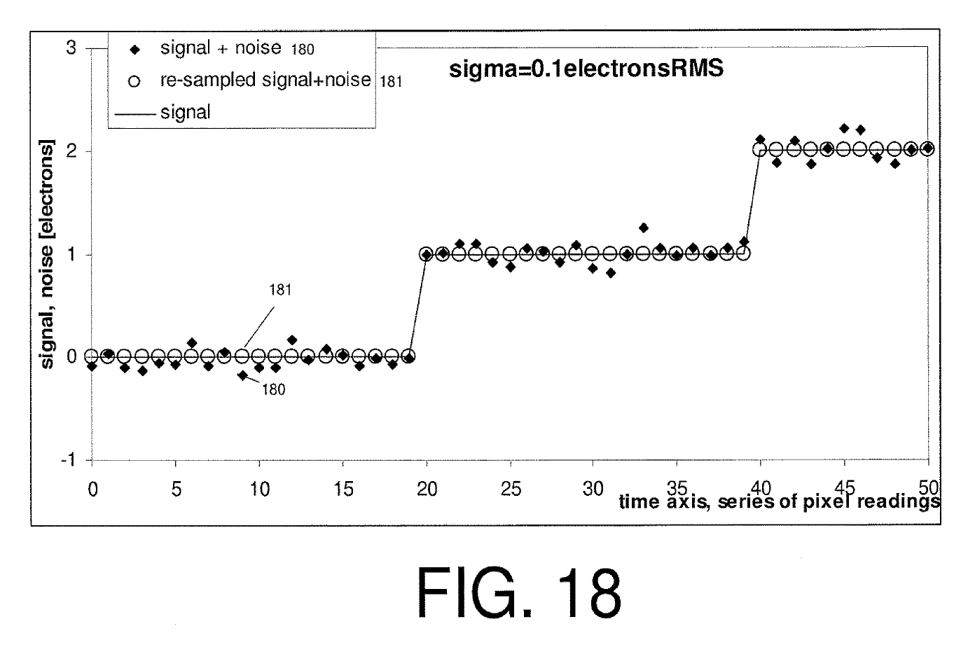

Methods in accordance with embodiments of the present invention bring the noise of semiconductor image sensors below the equivalent input noise of 1 electrons_{RMS}. Once an image sensor has a read noise performance sufficiently below 1 electrons_{RMS}, one can apply a further operator to effectively further reduce the read noise. In FIG. 16, FIG. 17, FIG. 18 a hypothetical series of 50 consecutive readings of the signal of a pixel with a certain RMS of read noise is shown; 1 electrons_{RMS} in FIG. 16, 0.25 electrons_{RMS} in FIGS. 17 and 0.1 electrons_{RMS} in FIG. 18. where by the resulting readings are resampled, i.e. rounded to the nearest integer number of electrons. Here the signal level starts at 0, and increases step-wise after 20 and 40 samples. The readings are subject to a predetermined level of noise. When the read noise in the readings is sufficiently below, e.g. is below 0.28 noise electrons_{RMS} as illustrated below, it becomes possible to discriminate steps in the signal, which steps correspond to a signal difference of 1 electron, as can be seen from FIG. 17 and FIG. 18.

The method is as follows: re-sample, or round, the readings 160, 170, 180 to their nearest integer number of electrons so as to form re-sampled readings 161, 171, 181. It is found that the RMS of the resampled population of readings 161, 171, 181 is lower than the RMS of the original readings 160, 170, 180.

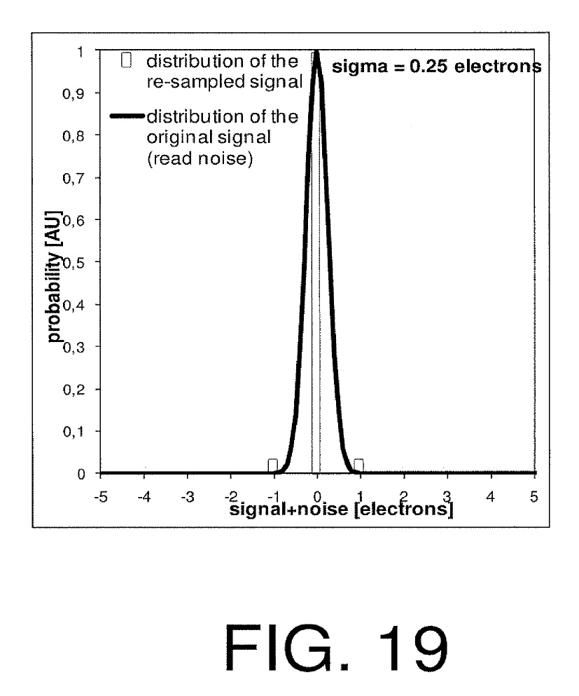

This is explained as follows. In FIG. 19, the probability distribution (normalized to 1 at maximum) for the reading of a fixed signal with a RMS or standard deviation sigma of 0.25 electrons_{RMS} is illustrated, hence corresponding to FIG. 17. The Gaussian distribution of 0.25 noise electrons is shown around an average “0”, see graph 190. Then each reading 170 in the population is rounded to the nearest integer 171, which results in a new discrete distribution 191 also shown in this FIG. 19. The RMS of the new, non-continuous, distribution is smaller than 0.25.

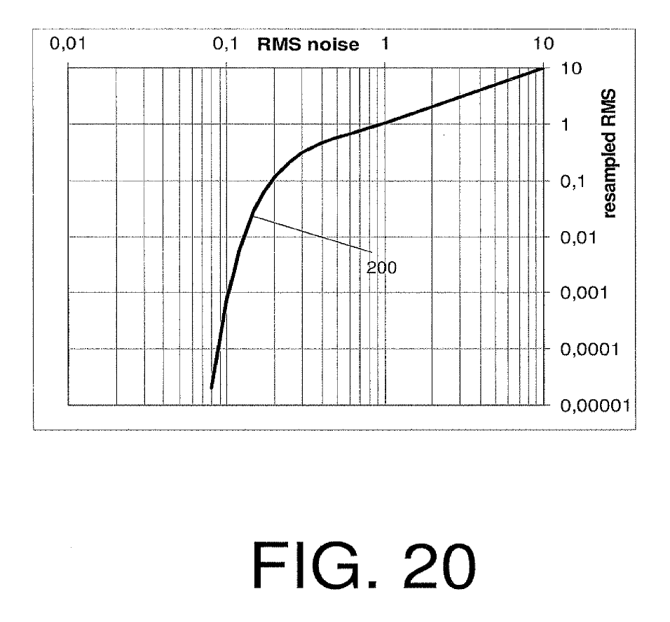

It turns out that one needs to start from a noise distribution that is already below 0.28 noise electrons in order to have an lower noise after re-sampling. This relation is shown in FIG. 20 which shows a graph 200 with as X-axis the noise of the reading of a pixel assuming that the read noise is a Gaussian distribution with a predetermined standard deviation expressed in electrons_{RMS}; and with as Y-axis the RMS or standard deviation of the resampled signal, also expressed in electrons_{RMS}. It is to be noted that the resampling results in a lower RMS when the original reading's noise is lower than 0.28 electrons_{RMS}. It can be seen from FIG. 20 that for noise >0.29 electrons_{RMS}, there is no effect (rather a limited adverse effect). The lower the initial noise, the more prominent is the improvement; e.g. for an initial reading's noise of 0.1 electrons_{RMS}, the resampled signal's noise drops with a factor of more than 100 (the resampled signal has a noise of only 0.00076 electrons_{RMS}), making this a virtually noise free system.

While the invention has been illustrated and described in detail in the drawings and foregoing description, such illustration and description are to be considered illustrative or exemplary and not restrictive. The invention is not limited to the disclosed embodiments.

For example, the concept of embodiments of the present invention is described hereinabove for 4T pixels, but in fact can apply to all pixels where a MOSFET is a key transistor of an amplifier, where this amplifier can for example be a source follower, a single ended amplifier, a differential amplifier, an operational amplifier, a transimpedance amplifier, cascoded amplifiers, isolation amplifiers, etc. It is to be noted also that SOI-FETs and FINFETS are essentially also MOSFETs, to which thus embodiments of the present invention may be applied. In fact in lieu of MOSFET one can read “a transistor for which cycling between bias states shortens the time correlation of its temporal (low frequency) noise”.

As another example, it is possible to operate the invention in an embodiment wherein instead of a 4T pixel, a 3T pixel, a pinned photoreceptor pixel or even a hybrid pixel is provided, more generally any type of pixels where detectors are separated from the readout IC (ROIC).

Embodiments of the present invention are applicable to visible light imaging, but also to all other electromagnetic wavelengths and to high energy particle detection.

Other variations to the disclosed embodiments can be understood and effected by those skilled in the art in practicing the claimed invention, from a study of the drawings, the disclosure and the appended claims. In the claims, the word “comprising” does not exclude other elements or steps, and the indefinite article “a” or “an” does not exclude a plurality. A The mere fact that certain measures are recited in mutually different dependent claims does not indicate that a combination of these measures cannot be used to advantage. Any reference signs in the claims should not be construed as limiting the scope.

1. A pixel comprising at least one transistor, the pixel being arranged for cycling the at least one transistor between two or more bias states during a readout phase, wherein the pixel is arranged for cycling the at least one transistor between two or more bias states by modulating a bulk potential of the at least one transistor.

2. A pixel according to claim 1, comprising a plurality of transistors wherein at least two transistors are provided in galvanically separated substrates, wherein the substrates are galvanically separated by any of a reverse biased junction, a dielectric layer, a physical separation.

3. A pixel according to claim 1, comprising a photoreceptor, wherein the photoreceptor has a potential gradient towards a location arranged for collecting charges.

4. A pixel according to claim 3, wherein the potential gradient is realized by a continuous or stepwise change in doping profile of the photoreceptor.

5. A pixel according to claim 3, wherein the potential gradient is realized by a continuous or stepwise change in doping profile of a pinning layer pinning the photoreceptor.

6. A pixel according to claim 3, wherein the potential gradient is realized by a continuous or stepwise change in doping level of the substrate in which the photoreceptor is located.

7. An image sensor comprising at least one pixel as in claim 1.

8. An image sensor according to claim 7, furthermore comprising a controller arranged for cycling the at least one transistor between the two or more bias states.

9. An image sensor according to claim 8, further comprising circuitry arranged for performing an operator on pixel samplings obtained after cycling of the at least one transistor between two or more bias states.

10. A pixel comprising at least one transistor, the pixel being arranged for cycling the at least one transistor between two or more bias states during a readout phase, wherein the pixel is arranged for cycling the at least one transistor between two or more bias states by modulating a gate potential of the at least one transistor.

11. A pixel comprising at least one transistor, the pixel being arranged for cycling the at least one transistor between two or more bias states during a readout phase, wherein the pixel is arranged for cycling the at least one transistor between two or more bias states by modulating a source and/or drain potential of the at least one transistor.
